(19) United States
(12) Patent Application Publication
(10) Pub. No.: US 2025/0364159 A1
(43) Pub. Date: Nov. 27, 2025

(54) SYSTEM FOR THE AUTOMATED MANUFACTURING OF A PREDETERMINED CABLE HARNESS AND MANUFACTURING METHOD OF THE CABLE HARNESS

(71) Applicant: Kromberg & Schubert Automotive GmbH & Co. KG, Renningen (DE)

(72) Inventor: Daniel Bechstein, Brackenheim (DE)

(21) Appl. No.: 19/169,559

(22) Filed: Apr. 3, 2025

(30) Foreign Application Priority Data
May 21, 2024 (DE) 10 2024 114 110.7

(51) Int. Cl. H01B 13/012; H01B 7/00

(52) U.S. Cl. CPC H01B 13/01209; H01B 13/01245; H01B 7/0045

(57) ABSTRACT

System for automated manufacturing of a predetermined cable harness from a plurality of individual components for cable harnesses has at least one handling device for laying the cable harness on a cable forming board, at least one control device for regulating and/or controlling the at least one handling device and at least one data storage,

The data storage contains individual component data of the plurality of individual components

The control device determines a cable harness trajectory based on the predetermined cable harness and the individual components required for said cable harness based on the individual component data

The handling device can be regulated and/or controlled by the control device for laying the predetermined cable harness in accordance with the determined cable harness trajectory and the required individual components.

### DESCRIPTION

The invention relates to a system for the automated manufacturing of a predetermined cable harness from a plurality of individual components for cable harnesses.

A large number of devices for the automated manufacturing of cable harnesses are known from the prior art. The individual cables of the cable harness to be manufactured must be laid on a cable forming board by a handling device. However, since corresponding cable forming boards cover more than one variant of the corresponding cable harness, for example due to special equipment, all laying paths can only be programmed manually with considerable effort. If changes are made, the laying paths must all be checked again and revised if necessary. This must be done manually by trained skilled in the art.

It is therefore an object of the present invention to provide a system for the automated manufacturing of a predetermined cable harness and a manufacturing method in which the manufacturing process is optimized for all variants

This object is achieved by the combination of features according to claim 1.

According to the invention, a system is proposed for the automated manufacturing of a predetermined cable harness from a plurality of individual components for cable harnesses, with at least one handling device, in particular a robot, preferably a multi-axis robot, for laying the cable harness on a cable forming board, at least one control device for regulating and/or controlling the at least one handling device and at least one data storage. The data storage contains individual component data for a large number of individual components. Furthermore, the control device is designed to determine a cable harness trajectory based on the predetermined cable harness and the individual components required for this cable harness based on the individual component data. In addition, the at least one handling device can be regulated and/or controlled by means of the control device for laying the predetermined cable harness in accordance with the determined cable harness trajectory and the required individual components.

The advantage of this is that not only the manufacturing process is optimized or shortened for all variants of a cable harness, but also because, for example, all components of the variants no longer have to be specified manually. In addition, the laying paths can be optimized and an improved cable length can be provided, thus reducing excess length and waste. In this way, a system for producing an optimized predetermined cable harness is provided based on a predetermined manufacturing order of the predetermined cable harness.

In an advantageous embodiment variant, it is provided that cable forming board data of a plurality of cable forming board components of the cable forming board are stored in the data storage. In addition, the control device is designed to determine the cable forming board components required for the predetermined cable harness based on the cable forming board data. Furthermore, the control device is designed to determine a configuration of the cable forming board based on the required individual components and the required cable forming board components. In this case, the at least one handling device can be regulated and/or controlled by means of the control device for laying the predetermined cable harness in accordance with the determined configuration of the cable forming board.

Preferably, the system is designed such that an interface is provided for the control device for providing a manufacturing order for the predetermined cable harness to be manufactured, in particular an input device for a manufacturing order for the predetermined cable harness. It is further advantageous if the input device is a computer which enables interaction with the environment, in particular a user.

In one exemplary embodiment of the invention, it is provided that the individual component data comprise at least geometric data of the plurality of individual components, preferably CAD data, and/or position data for the plurality of individual components, in particular plug positions in plug chambers and/or tapping positions, and/or manufacturing instructions and/or product planning data and/or product control data and/or parts lists.

Furthermore, an embodiment is favorable in which the plurality of individual components are at least taps and/or plugs and/or connectors and/or individual lines and/or contacts and/or contact carriers.

In a further advantageous variant, the invention provides that the cable forming board data comprise at least geometric data of the plurality of cable forming board components, preferably CAD data, and/or position data for the plurality of cable forming board components, in particular positions of laying forks and/or guides for a cable harness.

The system according to the invention is designed in one embodiment variant such that safety ranges and/or safety functions for controlling the handling device are stored in the control device.

In a preferred embodiment of the invention, the determination of the cable harness trajectory and of the required individual components can be carried out by means of an algorithm stored in the control device. Preferably, the algorithm comprises a hierarchical model for reducing a cable length of the predetermined cable harness and/or for increasing a laying speed of the predetermined cable harness and/or for reducing a waste of the predetermined cable harness.

In a further exemplary embodiment of the invention, the data storage is a dynamic data storage which can be updated in particular from a network. It is advantageous that current data is always available and that this data can also be continuously updated.

In an advantageous variant of the invention, it is provided that at least one detection device, in particular a sensor system, preferably an optical sensor system, is provided for detecting properties, in particular geometric properties, of at least the individual components and/or the required individual components and/or the cable forming board components and/or the required cable forming board components. In this way, the detected components, and in particular their arrangement and/or geometry, can be compared with the component data stored in the data storage by means of the control device.

According to the invention, a manufacturing method of a predetermined cable harness with a system according to the above disclosure is further proposed, in which a manufacturing order of the predetermined cable harness for the control device is provided. In addition, the cable harness trajectory and the required individual components of the predetermined cable harness are determined using the control device. Furthermore, the at least one handling device is regulated and/or controlled by means of the control device in accordance with the determined cable harness trajectory and the required individual components. The predetermined cable harness is completely and/or partially manufactured and/or laid during control by means of the at least one handling device.

In an advantageous embodiment variant of the method, it is provided that, before the regulation and/or control, a configuration of the cable forming board is determined by means of the control device on the basis of the required individual components and the required cable forming board components. In addition, the at least one handling device is regulated and/or controlled by means of the control device according to the determined configuration of the cable forming board.

In a further advantageous variant, the invention provides that at least during regulation and/or control, at least properties, in particular geometric properties, of at least the individual components and/or the required individual components, in particular and/or of the cable forming board components and/or the required cable forming board components are detected by means of the detection device, in particular the sensor system, preferably the optical sensor system. The detection is carried out by means of the detection device, in particular intermittently and/or continuously.

The features disclosed above can be combined in any way as long as such combination is technically feasible and said features do not contradict one another.

Other advantageous developments of the invention are characterized in the dependent claims and will be described in greater detail in the following, in conjunction with the description of the preferred embodiment of the invention, with reference to the figures. In the figures:

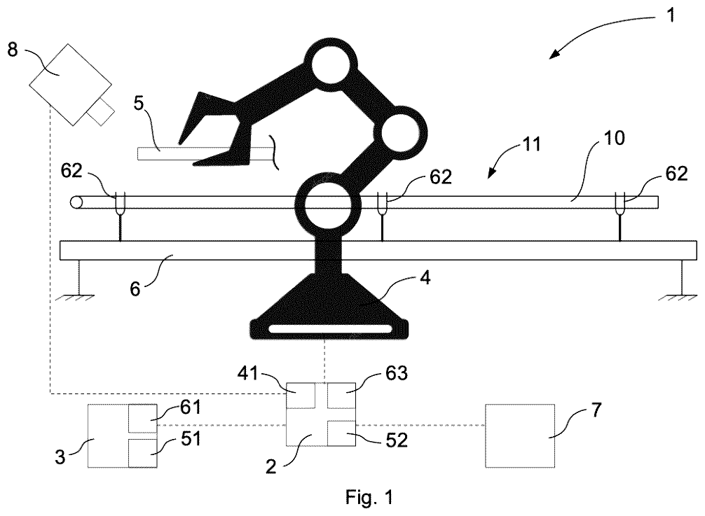

FIG. 1 shows a schematic view of a system for the automated manufacturing of a predetermined cable harness and

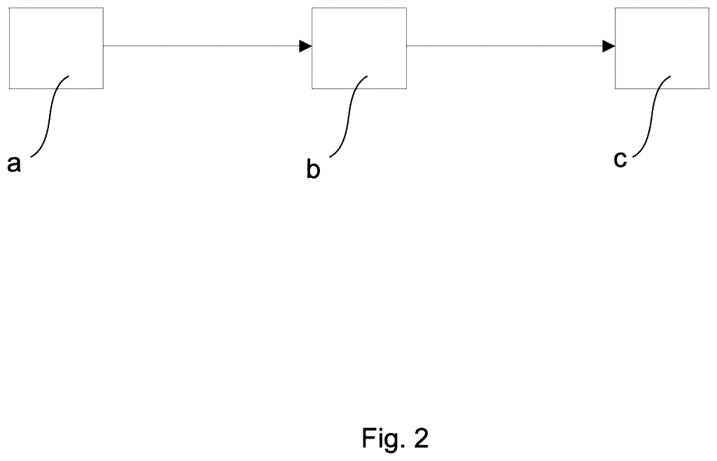

FIG. 2 shows a schematic profile of a manufacturing method.

The figures show schematic examples. Same reference numerals in the figures denote same functional and/or structural features.

FIG. 1 shows a schematic view of a system 1 for the automated manufacturing of a predetermined cable harness 10 from a plurality of individual components 5 for cable harnesses, with at least one handling device 4 for laying the cable harness 10 on a cable forming board 6, at least one control device 2 for regulating and/or controlling the at least one handling device 4 and at least one data storage 3.

The handling device 4 is a multi-axis robot. Furthermore, the data storage 3 is a dynamic data storage which can be updated from a network. The data storage 3 contains individual component data 51 of the plurality of individual components 5.

The control device 2 is designed to determine a cable harness trajectory 11 based on the predetermined cable harness 10 and the individual components 52 required for this cable harness 10 based on the individual component data 51. In addition, the at least one handling device 4 can be regulated and/or controlled by means of the control device 2 for laying the predetermined cable harness 10 in accordance with the determined cable harness trajectory 11 and the required individual components 52. Furthermore, safety ranges and/or safety functions 41 for controlling the handling device 4 are stored in the control device 2. In addition, the determination of the cable harness trajectory 11 and the required individual components 52 can be carried out by means of an algorithm stored in the control device 2. Preferably, the algorithm comprises a hierarchical model for reducing a cable length of the predetermined cable harness 10 and/or for increasing a laying speed of the predetermined cable harness 10 and/or for reducing a waste of the predetermined cable harness 10.

The plurality of individual components 5 are at least taps and/or plugs and/or connectors and/or individual cables and/or contacts and/or contact carriers. Furthermore, the individual component data 51 comprise at least geometric data of the plurality of individual components 5, preferably CAD data, and/or position data for the plurality of individual components 5, in particular plug positions in plug chambers and/or tapping positions, and/or manufacturing instructions and/or product planning data and/or product control data and/or parts lists.

In addition, cable forming board data 61 of a plurality of cable forming board components 62 of the cable forming board 6 are stored in the data storage 3. In addition, the control device 2 is designed to determine the cable forming board components 63 required for the predetermined cable harness 10 based on the predetermined cable harness 10 and the cable forming board data 61. In particular, the control device is designed to determine a configuration of the cable forming board 6 based on the required individual components 51 and the required cable forming board components 63. Moreover, the at least one handling device 4 can be regulated and/or controlled by means of the control device 2 for laying the predetermined cable harness 10 in accordance with the determined configuration of the cable forming board 6.

The cable forming board data 61 comprise at least geometric data of the plurality of cable forming board components 62, preferably CAD data, and/or position data for the plurality of cable forming board components 62, in particular positions of laying forks and/or guides for a cable harness.

Furthermore, an interface 7 is provided for the control device 2 for providing a manufacturing order of the predetermined cable harness 10 to be manufactured. In the present embodiment, the input device is a computer that enables interaction with the environment, in particular a user.

FIG. 1 also shows that at least one detection device 8 is provided for detecting properties, in particular geometric properties, of at least the individual components 5 and/or the required individual components 52 and/or the cable forming board components 62 and/or the required cable forming board components 63. The detection device 8 is an optical sensor system.

FIG. 2 shows a schematic sequence of a manufacturing method of a predetermined cable harness 10 with the system 1 shown in FIG. 1.

In the manufacturing method, a manufacturing order for the predetermined cable harness 1 is first provided for the control device 2. The cable harness trajectory 11 and the required individual components 52 of the predetermined cable harness are then determined by means of the control device 2 and then the at least one handling device 4 is regulated and/or controlled by means of the control device 2 in accordance with the determined cable harness trajectory 11 and the required individual components 52. The predetermined cable harness 10 is completely and/or partially manufactured and/or laid during regulation by means of the at least one handling device 4.

Before regulating and/or controlling, a configuration of the cable forming board 6 is determined by means of the control device 2 based on the required individual components 51 and the required cable forming board components 63. In addition, the at least one handling device 4 is regulated and/or controlled by means of the control device 2 according to the determined configuration of the cable forming board 6.

In addition, during regulation and/or control, at least properties, in particular geometric properties, of at least the individual components 5 and/or the required individual components 52, in particular and/or the cable forming board components 62 and/or the required cable forming board components 6 are recorded intermittently and/or continuously by means of the recording device 8.

The invention is not limited in its form to the preferred exemplary embodiments provided above. Rather, a number of variants is conceivable, which make use of the presented solution even with fundamentally different designs.

1. A system (1) for the automated manufacturing of a predetermined cable harness (10) from a plurality of individual components (5) for cable harnesses, with at least one handling device (4) for laying the cable harness (10) on a cable forming board (6), at least one control device (2) for regulating and/or controlling the at least one handling device (4) and at least one data storage (3),
wherein the data storage (3) contains individual component data (51) of the plurality of individual components (5),
wherein the control device (2) is designed to determine a cable harness trajectory (11) based on the predetermined cable harness (10) and the individual components (52) required for this cable harness (10) based on the individual component data (51),
wherein the at least one handling device (4) can be regulated and/or controlled by means of the control device (2) for laying the predetermined cable harness (10) in accordance with the determined cable harness trajectory (11) and the required individual components (52).

2. The system (1) according to claim 1, wherein cable forming board data (61) of a plurality of cable forming board components (62) of the cable forming board (6) are stored in the data storage (3), wherein the control device (2) is designed to use the predetermined cable harness (10) to determine the cable forming board components (63) required for said cable harness (10) using the cable forming board data (61), wherein the control device is designed to determine a configuration of the cable forming board (6) based on the required individual components (51) and the required cable forming board components (63), wherein the at least one handling device (4) can be regulated and/or controlled by means of the control device (2) for laying the predetermined cable harness (10) in accordance with the determined configuration of the cable forming board (6).

3. The system (1) according to claim 1, wherein an interface (7) is provided for the control device (2) for providing a manufacturing order of the predetermined cable harness (10) to be manufactured.

4. The system according to claim 1, wherein the individual component data (51) comprise at least geometric data of the plurality of individual components (5), preferably CAD data, and/or position data for the plurality of individual components (5), in particular plug positions in plug chambers and/or tapping positions, and/or manufacturing instructions and/or product planning data and/or product control data and/or parts lists.

5. The system (1) according to claim 1, wherein the plurality of individual components (5) are at least taps and/or plugs and/or connectors and/or individual cables and/or contacts and/or contact carriers.

6. The system (1) according to claim 2, wherein the cable forming board data (61) comprise at least geometric data of the plurality of cable forming board components (62), preferably CAD data, and/or position data for the plurality of cable forming board components (62), in particular positions of laying forks and/or guides for a cable harness.

7. The system according to claim 1, wherein safety ranges and/or safety functions (41) for controlling the handling device (4) are stored in the control device (2).

8. The system (1) according to claim 1, wherein the determination of the cable harness trajectory (11) and of the required individual components (52) can be carried out by means of an algorithm stored in the control device (2).

9. The system (1) according to claim 8, wherein the algorithm comprises a hierarchical model for reducing a cable length of the predetermined cable harness (10) and/or for increasing a laying speed of the predetermined cable harness (10) and/or for reducing a waste of the predetermined cable harness (10).

10. The system (1) according to claim 1, wherein the data storage (3) is a dynamic data storage which can be updated in particular from a network.

11. The system (1) according to claim 2, wherein at least one detection device (8) is provided for detecting properties, in particular geometric properties, of at least the individual components (5) and/or of the required individual components (52) and/or the cable forming board components (62) and/or the required cable forming board components (63).

12. A manufacturing method of a predetermined cable harness (10) with a system (1) according to claim 2, comprising the steps:
a. providing a manufacturing order of the predetermined cable harness (1) for the control device (2);
b. determining the cable harness trajectory (11) and the required individual components (52) of the predetermined cable harness using the control device (2);
c. regulating and/or controlling the at least one handling device (4) by means of the control device (2) in accordance with the determined cable harness trajectory (11) and the required individual components (52),
wherein the predetermined cable harness (10) is completely and/or partially manufactured and/or laid during control by means of the at least one handling device (4).

13. The manufacturing method of a predetermined cable harness (10) according to claim 12, wherein prior to the regulation and/or control, a configuration of the cable forming board (6) is determined by means of the control device (2) on the basis of the required individual components (51) and the required cable forming board components (63), wherein the at least one handling device (4) is regulated and/or controlled by means of the control device (2) in accordance with the determined configuration of the cable forming board (6).

14. The manufacturing method of a predetermined cable harness (10) according to claim 12, wherein at least during regulation and/or control, at least properties, in particular geometric properties, of at least the individual components (5) and/or the required individual components (52), in particular and/or the cable forming board components (62) and/or the required cable forming board components (63) are detected by means of the detection device (8), wherein the detection by means of the detection device (8) takes place, in particular intermittently and/or continuously.
